(19) United States
(12) Patent Application Publication
(10) Pub. No.: US 2021/0143030 A1
(43) Pub. Date: May 13, 2021

(54) WAFER TO WAFER BONDING APPARATUS, WAFER TO WAFER BONDING SYSTEM, AND WAFER TO WAFER BONDING METHOD

(71) Applicant: Samsung Electronics Co., Ltd., Suwon-si (KR)

(72) Inventors: Kyeongbin Lim, Seoul (KR); Junhyung Kim, Yongin-si (KR); Siwoong Woo, Hwaseong-si (KR); Seungdae Seok, Seongnam-si (KR)

(21) Appl. No.: 16/911,919

(22) Filed: Jun. 25, 2020

(30) Foreign Application Priority Data
Nov. 11, 2019 (KR) 10-2019-0143486

(51) Int. Cl. H01L 21/67; H01L 21/683; H01L 33/00; H01L 21/68; H01L 33/48

(52) U.S. Cl. CPC H01L 21/67092; H01L 21/6838; H01L 33/486; H01L 33/0093; H01L 21/682; H01L 21/67098

(57) ABSTRACT

A wafer bonding apparatus includes a lower stage having a first surface and holding a first wafer on the first surface, an upper stage having a second surface and holding a second wafer on the second surface, an upper push rod passing through a center hole of the upper stage to press a middle region of the second wafer, and a plurality of first heating circuits provided at the second surface of the upper stage to heat the second wafer held by the upper stage. Each of the plurality of first heating circuits is independently controlled such that the second wafer is heated to have different temperature distributions along a circumferential direction about a center of the second wafer.

### PRIORITY STATEMENT

This application claims priority under 35 U.S.C. § 119 to Korean Patent Application No. 10-2019-0143486, filed on Nov. 11, 2019 in the Korean Intellectual Property Office (KIPO), the contents of which are herein incorporated by reference in their entirety.

### BACKGROUND

### 1. Field

Example embodiments relate to a wafer bonding apparatus, a wafer to wafer bonding system and a wafer to wafer bonding method. More particularly, example embodiments relate to an apparatus for boding wafers to each other to manufacture a semiconductor device having a three-dimensional connection structure, a wafer to wafer bonding apparatus and a wafer to wafer bonding method.

### 2. Description of the Related Art

In manufacturing electronic products such as a CIS (CMOS image sensor), an HBM (High Bandwidth Memory), etc., two wafers may be bonded to each other, thereby increasing a production yield per wafer. The wafer to wafer bonding process may include an O2 plasma activation step, a hydration step, a wafer alignment step, a wafer bonding step, an annealing step, etc. In the wafer bonding step, a middle region of a first wafer may be deformed to protrude toward a second wafer and then may be joined with the second wafer gradually from the middle region to a peripheral region. Local portions of at least one of the first and second wafers may be deformed due to initial warpage of the wafer, anisotropy of the wafer material, and the like, thereby resulting in bonding errors between junction points in the wafers.

### SUMMARY

Example embodiments provide a wafer bonding apparatus capable of improving wafer to wafer bonding accuracy.

Example embodiments provide a wafer to wafer bonding system capable of improving wafer to wafer bonding accuracy.

Example embodiments provide a wafer to wafer bonding method using the wafer to wafer bonding system.

According to an exemplary embodiment of the present inventive concept, a wafer bonding apparatus includes a lower stage having a first surface and configured to hold a first wafer on the first surface, an upper stage having a second surface and configured to hold a second wafer on the second surface, an upper push rod configured to pass through a center hole of the upper stage to press a middle region of the second wafer, and a plurality of first heating circuits provided at the second surface of the upper stage to heat the second wafer held by the upper stage. Each of the plurality of first heating circuits is configured to be independently controlled such that the second wafer is heated to have different temperature distributions along a circumferential direction about a center of the second wafer.

According to an exemplary embodiment of the present inventive concept, a wafer bonding apparatus includes a lower stage having a first surface and configured to hold a first wafer on the first surface, an upper stage having a second lower surface and a second upper surface opposite thereto, the second lower surface being configured to hold a second wafer, and the upper stage including a center hole extending from the second upper surface to the second lower surface, an upper push rod configured to pass through the center hole of the upper stage to press a middle region of the second wafer, a plurality of first heating circuits provided at the second lower surface of the upper stage to heat the second wafer, and a power controller configured to independently control the plurality of first heating circuits to perform a first local heat treatment on a first region of the second wafer and a second local heat treatment on a second region of the second wafer.

According to an exemplary embodiment of the present inventive concept, a wafer to wafer bonding system includes an alignment apparatus including an alignment stage and configured to load a first wafer and a second wafer on the alignment stage, the alignment stage supporting and aligning the first wafer and the second wafer, a wafer bonding apparatus configured to receive the aligned first wafer and the aligned second wafer and to bond the aligned first wafer and the aligned second wafer to each other, the wafer bonding apparatus including an upper stage and a lower stage which are configured to hold the aligned first wafer and the aligned second wafer, respectively, a plurality of first heating circuits provided in the upper stage to heat the aligned first wafer, and a power controller configured to independently control a heating value of each of the plurality of first heating circuits on a respective region of the aligned first wafer.

According to example embodiments, a wafer bonding apparatus and a wafer to wafer bonding system may include a plurality of heat elements provided in an upper stage (lower stage or alignment stage) to heat a wafer. Before bonding the wafers, heating values of the heating elements may be controlled independently based on alignment error information, to perform local heat treatment on the wafer.

Thus, heat from the heating elements may be transferred to the wafer in contact or non-contact form to thereby minimize the alignment error between the wafers.

### BRIEF DESCRIPTION OF THE DRAWINGS

Example embodiments will be more clearly understood from the following detailed description taken in conjunction with the accompanying drawings. FIGS. 1 to 14 represent non-limiting, example embodiments as described herein.

FIG. 1 is a block diagram illustrating a wafer to wafer bonding system in accordance with example embodiments.

FIG. 2 is a cross-sectional view illustrating a wafer bonding apparatus in accordance with example embodiments.

FIG. 3 is a cross-sectional view illustrating an initial step of a wafer bonding process in the wafer bonding apparatus in FIG. 2.

FIG. 4 is a plan view illustrating an upper stage of the wafer bonding apparatus in FIG. 2.

FIG. 5 is a block diagram illustrating a controller and a power controller for controlling a heating device provided in the upper stage in FIG. 4.

FIG. 6 is a block diagram illustrating a first group of heating elements of a heating device and a power controller in FIG. 4.

FIG. 7 is a block diagram illustrating a second group of heating elements of a heating device and a power controller in FIG. 4.

FIG. 8 is a graph illustrating silicon transmissivity as a function of wavelength of light irradiated from a heating device in FIG. 4.

FIGS. 9A and 9B are views illustrating alignment error maps with respect to crystal orientations of first and second wafers to be bonded.

FIG. 10 is graphs illustrating alignment errors at wafer radius between the first and second wafers bonded by a wafer bonding apparatus according to a comparative embodiment and an example embodiment.

FIG. 11 is a plan view illustrating an alignment apparatus in accordance with example embodiments.

FIG. 12 is a flowchart illustrating a wafer to wafer bonding method in accordance with example embodiments.

FIG. 13 is a view illustrating the wafer to wafer bonding method in FIG. 12.

FIG. 14 is a flowchart illustrating a bonding stage of the wafer to wafer bonding method in FIG. 12.

### DETAILED DESCRIPTION OF EXAMPLE EMBODIMENTS

Hereinafter, example embodiments will be explained in detail with reference to the accompanying drawings.

FIG. 1 is a block diagram illustrating a wafer to wafer bonding system according to exemplary embodiments.

Referring to FIG. 1, a wafer to wafer bonding system 10 may include a pre-treatment apparatus such as a plasma processing apparatus 40 and a cleaning apparatus 50, an alignment apparatus 60, and a wafer bonding apparatus 70 arranged in a clean room 20. The wafer to wafer bonding system 10 may further include a cassette stage 30 disposed in a side of the clean room 20, for example.

In example embodiments, the clean room 20 may be an enclosed room having a cuboid shape, and may be a controlled environment that has a low level of pollutants such as, for example, dust, airborne microbes, aerosol particles, and chemical vapors.

The cassette stage 30 may provide a space in which wafers are located before being transferred into the clean room 20. A carrier C having a plurality of the wafers received therein may be supported on a support plate 32 of the cassette stage 30. The carrier C may be, for example, a front opening unified pod (FOUP). The wafers received in the carrier C may be transferred into the clean room 20 by a transfer robot 22. For example, three carriers C may be disposed on the cassette stage 30. In exemplary embodiments, first and second carriers C may provide first and second wafers to the clean room 20, respectively, and a third carrier C may receive bonded wafers from the clean room 20. The present invention is not limited thereto. In an exemplary embodiment, the third carrier C may be omitted from the cassette stage 30 when the bonded wafers are returned to at least one of the first and second carriers C.

In example embodiments, the first wafer may be a wafer in which circuits for an image sensor chip are formed, and the second wafer may be a wafer in which photosensors for the image sensor chip are formed. In exemplary embodiments, the first wafer may be a wafer in which High Bandwidth Memory (HBM) controller circuits for a semiconductor package such as a HBM are formed, and the second wafer may be a wafer in which memories for the semiconductor package are formed. In an exemplary embodiment, the memories may include dynamic random access memories (DRAMs)

The plasma processing apparatus 40 may perform a plasma treatment on a surface of a wafer. The plasma processing apparatus 40 may be an apparatus configured to generate plasma on the surface of the wafer. In an exemplary embodiment, the plasma processing apparatus may include an ICP (inductively coupled plasma) chamber. When the wafer is processed with the plasma, a dangling bond may be formed on the surface of the wafer. However, the plasma generated by the plasma processing apparatus is not limited to inductively coupled plasma utilized in the ICP chamber. For example, exemplary embodiments may utilize capacitively coupled plasma, microwave plasma, etc., which may be generated by the plasma processing apparatus.

The cleaning apparatus 50 may clean the surface of the wafer that has been plasma-processed by the plasma processing apparatus 40. The cleaning apparatus 50 may coat deionized (DI) water on the wafer surface using a spin coater. The DI water may clean the wafer surface and allow —OH radical to be bonded easily on the wafer surface, such that dangling bonds are easily created on the wafer surface.

The alignment apparatus 60 may align the wafer by detecting a flat portion (or a wafer notch) of the wafer. The flat portion (or the wafer notch) may indicate a crystal orientation direction (e.g., [100] or [110]). The wafer aligned by the alignment apparatus 60 may be transferred to the plasma processing apparatus 40 or the wafer bonding apparatus 70 by the transfer robot 22. The alignment apparatus 60 may be provided as a loading unit for loading the aligned wafer into the wafer bonding apparatus 70. The wafer bonding apparatus 70 may hold the loaded first wafer and second wafer by suction, for example, and bond the loaded first wafer and the loaded second wafer to each other. As described later, at least one of the alignment apparatus 60 and the wafer bonding apparatus 70 may include a heating device which performs local heat treatment on the wafer in order for wafer temperature distribution control.

Hereinafter, the wafer bonding apparatus 70 of FIG. 1 will be explained.

FIG. 2 is a cross-sectional view illustrating a wafer bonding apparatus in accordance with example embodiments. FIG. 3 is a cross-sectional view illustrating an initial step of a wafer bonding process in the wafer bonding apparatus in FIG. 2. FIG. 4 is a plan view illustrating an upper stage of the wafer bonding apparatus in FIG. 2. FIG. 5 is a block diagram illustrating a controller and a power controller for controlling a heating device provided in the upper stage in FIG. 4. FIG. 6 is a block diagram illustrating a first group of heating elements of a heating device and a power controller in FIG. 4. FIG. 7 is a block diagram illustrating a second group of heating elements of a heating device and a power controller in FIG. 4. FIG. 6 is a cross-sectional view taken along line A-A′ in FIG. 4, and FIG. 7 is a cross-sectional view taken along line B-B′ in FIG. 4. FIG. 8 is a graph illustrating silicon transmissivity as a function of wavelength of light irradiated from a heating device in FIG. 4. FIGS. 9A and 9B are views illustrating alignment error maps with respect to crystal orientations of first and second wafers to be bonded. FIG. 10 is graphs illustrating alignment errors at wafer radius between the first and second wafers bonded by a wafer bonding apparatus according to a comparative embodiment and an example embodiment.

Referring to FIGS. 2 to 10, a wafer bonding apparatus 70 may include a lower chuck structure 100, an upper chuck structure 200, a wafer push unit 320 and a heating device. Additionally, the wafer bonding apparatus 70 may further include a power controller configured to control power supplied to the heating device and a controller 600 configured to control operations of the power controller.

In example embodiments, the lower chuck structure 100 may include a lower stage 110 that holds a first wafer W1. The lower stage 110 may have a first surface 112 on which the first wafer W1 is disposed. First suction holes 130 may extend to the first surface 112 of the lower stage 110 on which a suction force acts via the first suction holes 130. The first wafer W1 may be vacuum suctioned via air intake by the first suction holes 130 of the lower stage 110.

The upper chuck structure 200 may include an upper stage 210 that holds a second wafer W2. The upper stage 210 may be arranged to face the lower stage 110. The upper stage 210 may have a second surface 212 on which the second wafer W2 is disposed. Second suction holes 230 may extend to the second surface 212 of the upper stage 210 on which a suction force acts via the second suction holes 230. The second wafer W2 may be vacuum suctioned via air intake by the second suction holes 230 of the upper stage 210.

The first suction holes 130 of the lower stage 110 and the second suction holes 230 of the upper stage 210 may be arranged to correspond to each other. For example, the first suction holes 130 and the second suction holes 230 may be arranged mirror-symmetrically to each other. In an exemplary embodiment, each of the first suction holes 130 of the lower stage 110 may vertically overlap a respective one of the second suction holes 230 of the upper stage 210.

As illustrated in FIG. 4, the second suction holes 230 may be arranged in a peripheral region of the upper stage 210 to provide an outer suction region. The second suction holes 230 may suction a peripheral portion of the second wafer W2. Although it is not illustrated in the figures, inner suction holes may be additionally formed in a middle region of the upper stage 210 to provide an inner suction region. Because the first suction holes 130 correspond to the second suction holes 230, a detailed explanation concerning the first suction holes 130 will be omitted. In an exemplary embodiment, the lower stage 110 and the upper stage 210 may have the same in size and configuration of suction holes.

The second suction holes 230 may have a first suction portion Z1, a second suction portion Z2 and a third suction portion Z3 arranged sequentially in a radial direction from a center of the upper stage 210. For example, each of the first to third suction portions Z1, Z2, Z3 may include eight segments of an arch shape to have an annular form. In this embodiment, each of the first to third suction portions has eight arch-shaped segments, however, it may not be limited thereto. In an exemplary embodiment, the suction portion may have a number of arch-shaped segments between 8 to 64 such as 16, 32, 64, etc.

The second suction holes 230 may be positioned in the peripheral region of the upper stage 210. In an exemplary embodiment, the peripheral region may be a region between at least 0.6 R from the center of the upper stage 210 and 1 R. The notation “R” represents a half diameter of the upper stage 210, “0.6 R” represents 60 percent of the half diameter, and “1 R” represents 100 percent of the half diameter. In an exemplary embodiment, the peripheral region may be a region between 0.8 R and 1 R. In case that the wafer has a diameter of 300 mm, the first suction portion Z1 may have an inner radius of about 133 mm and an outer radius of about 136 mm from the center of the upper stage 210, the second suction portion Z2 may have an inner radius of about 139 mm and an outer radius of about 142 mm from the center of the upper stage 210, and the third suction portion Z3 may have an inner radius of about 145 mm and an outer radius of about 148 mm from the center of the upper stage 210. A width in the radial direction of each of the first to third suction portions Z1, Z2, Z3 may be about 3 mm, however, it may not be limited thereto, for example, the width in the radial direction may have a width between about 1 mm to about 5 mm. In an exemplary embodiment, the radial width of each of the first to third suction portions Z1, Z2, Z3 may be the same as or different from each other. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

Each of the first to third suction portions Z1, Z2, Z3 having the annular shape may include a plurality of recesses having an arch shape. For example, each of the first to third suction portions Z1, Z2, Z3 may have eight recesses of an arch shape. One recess may have a central angle of about 45 degrees. It may be understood that the numbers and shapes of the suction portions and the recesses may not be limited thereto.

The first to third suction portions Z1, Z2, Z3 may be connected to a vacuum pump (not illustrated) through pipelines respectively. For example, vacuum pressure may be supplied independently or in groups (for example, a group having arch-shaped recesses opposite to each other) to eight arch-shaped segments of the first suction portion Z1.

The suction pump may be connected to and controlled by the controller 600 to supply the vacuum pressure to the first to third suction portions Z1, Z2, Z3. Additionally, the suction pump may supply the vacuum pressure to each of the recesses of the first to third suction portions Z1, Z2, Z3.

For example, when the vacuum pressure is supplied to the first to third suction portions Z1, Z2, Z3, a first vacuum region of a first suction area may be formed in the peripheral region of the upper stage 210. When the vacuum pressure is supplied to the second and third suction portions Z2, Z3, a second vacuum region of a second suction area less than the first suction area may be formed in the peripheral region of the upper stage 210. When the vacuum pressure is supplied to the third suction portions Z3 (Z3: ON), a third vacuum region of a third suction area less than the second suction area may be formed on the peripheral region of the upper stage 210.

A ratio of the suction areas of the upper stage 210 and the lower stage 110 may be controlled to change according to bonding propagation. The suction area formed in the upper stage 210 may be controlled to be asymmetric to the suction area formed in the lower stage 110. For example, at a first time point of the bonding propagation, the suction area of the first suction area may be provided in the upper stage 210 and the suction area of the third suction area may be provided in the lower stage 110.

The holding of the first and second wafers W1, W2 may be implemented in various ways. For example, as described above, the first and second wafers W1, W2 may be vacuum suctioned by the first and second suction holes 130, 230 respectively. In an exemplary embodiment, the first and second wafers W1, W2 may be held by an electrostatic chuck using electrostatic force. In this case, the ratio of the suction areas of the upper stage 210 and the lower stage 110 may be controlled to change according to the bonding propagation.

In example embodiments, the lower chuck structure 100 may include a lower stage driving portion 120 which moves the lower stage 110. The lower stage driving portion 120 may include a horizontal driving portion to move linearly the lower stage 110 in X, Y, Z directions and a rotational driving portion to rotate the lower stage 110 about the Z direction.

The lower stage 110 may be installed to be movable linearly and rotationally by the lower stage driving portion 120 such that a relative position between the upper stage 210 and the lower stage 110 may be adjusted. As described later, the lower stage 110 may be movable upwardly and downwardly in the Z direction by the lower stage driving portion 120. Accordingly, the lower stage 110 may move the first wafer W1 suctioned thereon toward the second wafer W2 suctioned on the upper stage 210.

The upper chuck structure 200 may include an upper stage driving portion 220 which moves the upper stage 210. The upper stage driving portion 220 may perform similar functions as the lower stage driving portion 120.

In example embodiments, the wafer push unit 320 may include an upper push rod 322 and an upper push rod driving portion 324. The upper push rod 312 of the wafer push unit 320 may move (or press) downwardly by the upper push rod driving portion 324 to apply a pressure to a middle region of the second wafer W2. In an exemplary embodiment, a second wafer push unit may be further provided to apply a pressure to the middle region of the first wafer W2 upwardly.

The upper push rod driving portion 324 may be connected to and controlled by the controller 600 and may move the upper push rod 322 upwardly and downwardly. The upper push rod 322 may be installed to be movable through a center hole 214 formed in the middle portion of the upper stage 210. The upper push rod 322 may move downwardly by the upper push rod driving portion 324 to apply pressure to the middle region of the second wafer W2. The upper push rod driving portion 324 may include a driving mechanism such as a hydraulic cylinder, a pneumatic cylinder, a linear motor, a solenoid device, etc.

For example, the controller 600 may control a protruding length T of the upper push rod 322 from the upper stage 210. In an exemplary embodiment, the protruding length T may be defined as a length between a bottom surface of the upper stage 210 and a lower end of the upper push rod 322. The protruding length T of the upper push rod 322 may be controlled to change according to the bonding propagation.

Although it is not illustrated in the figures, the wafer bonding apparatus 70 may further include a detection sensor such as a vision camera. The detection sensor may detect an alignment key formed on the wafer through a detection hole formed in the upper stage 210, and the controller 600 may align the first and second wafers based on the detected information. Additionally, the vision camera may detect a bonding propagation position of the wafer through the detection hole. The vision camera may output the detected wafer position information to the controller 600, and the controller 600 may calculate the bonding propagation position of the first and second wafers based on the inputted position information and control the operations of the wafer bonding apparatus 70.

For example, the controller 600 may be connected to elements of the wafer bonding apparatus 70 to control operations thereof. The controller 600 may receive the position information from the detection sensor and determine the bonding propagation position of the first and second wafers W1, W2 based on the position information. The controller 600 may apply driving control signals to the driving portions such as the lower stage driving portion 120, the vacuum pump, the lower push rod driving portion and the upper push rod driving portion 324 to control the operation of the wafer bonding apparatus 70.

In example embodiments, the heating device may include a plurality of heating elements 400 provided in the first surface 112 of the lower stage 110 and/or the second surface 212 of the upper stage 210 to heat the first wafer W1 and/or the second wafer W2. The heating elements 400 may be connected to the power controller, and the power controller may control independently the powers supplied to the heating elements 400 by the control of the controller 600. The powers of the heating elements 400 may be controlled independently to perform local heat treatment on the wafer.

As illustrated in FIGS. 4 to 7, the heating device may include a plurality of the heating elements 400 provided in the second surface 212 of the upper stage 210 to heat the second wafer W2. The powers of the plurality of the heating elements 400 may be controlled independently such that the second wafer W2 is heated to have different temperature distributions along a circumferential direction about a center of the second wafer W2. For example, the heating elements 400 may be positioned between the center of the upper stage 210 and at least 0.6 R of a radius (R) from the center of the upper stage 210. In an exemplary embodiment, the heating elements 400 may be positioned between the center of the upper stage 210 and 0.8 R.

The upper stage 210 may have a first region A and a second region B which are arranged alternately in a circumferential direction about the center. A plurality of the heating elements 400 may include a first group of heating elements 412 disposed in the first region A and a second group of heating elements 422 disposed in the second region B.

For example, the first region A and the second region B may have a central angle of about 45 degrees. The first region A may extend in a first (radial) direction (X direction) corresponding to a first crystal orientation of the second wafer W2, and the second region B may extend in a second (radial) direction (45° direction to X direction) corresponding to a second crystal orientation of the second wafer W2. For example, the first crystal orientation of the second wafer W2 may be [100] direction and the second crystal orientation of the second wafer W2 may be [110]. The first region A and the second region B may be arranged alternately along the circumferential direction about the center. Each of the first and second regions A, B may have a sector shape with the central angle of 45°.

In example embodiments, the first group of heating elements 412 may include at least two subgroups of heating elements arranged in a first radial direction from the center, and the second group of heating elements 422 may include at least two subgroups of heating elements arranged in a second radial direction from the center.

For example, the first region A may have first, second and third sub-regions A1, A2, A3 arranged sequentially in the first radial direction from the center, and the second region B may have fourth, fifth and sixth sub-regions B1, B2, B3 arranged sequentially in the second radial direction from the center. The first sub-region A1 and the fourth sub-region B1 may have the same shape, the second sub-region A2 and the fifth sub-region B2 may have the same shape, and the third sub-region A3 and the sixth sub-region B3 may have the same shape.

The first group of heating elements 412 may include a first subgroup of heating elements 412-1, a second subgroup of heating elements 412-2 and a third subgroup of heating elements 412-3 disposed in the first, second and third sub-regions A1, A2, A3 respectively. The second group of heating elements 422 may include a fourth subgroup of heating elements 422-1, a fifth subgroup of heating elements 422-2 and a sixth subgroup of heating elements 422-3 disposed in the fourth, fifth and sixth sub-regions B1, B2, B3 respectively.

As illustrated in FIG. 5, the power controller may be connected to the controller 600 and may supply the powers independently to the heating elements 400 by the control of the controller 600. For example, the power controller may include a first power supply 512 configured to supply powers to the first to third subgroups (i.e., a first set of heating elements) of heating elements 412-1, 412-2, 412-3 installed in the upper stage 210 and a second power supply 522 configured to supply powers to the fourth, fifth and sixth subgroups (i.e., a second set of heating elements) of heating elements 422-1, 422-2, 422-3 installed in the upper stage 210.

Additionally, the power controller may include a third power supply 510 configured to supply powers to first to third subgroups of heating elements installed in the lower stage 110 and a fourth power supply 520 configured to supply powers to fourth, fifth and sixth subgroups of heating elements installed in the lower stage 110.

As illustrated in FIGS. 6 and 7, the heating element 400 may include a heating circuit such as a LED (light emitting diode) lamp. The LED lamp may be installed to be exposed from the second surface 212 of the upper stage 210. The LED lamp may irradiate light onto the second wafer W2 suctioned on the upper stage 210 to locally heat the second wafer W2 using radiant heat. The heating element 400 may be in contact with the second wafer W2 suctioned on the upper stage 210 to locally heat the second wafer W2 using conductive heat. The term “contact,” as used herein, refers to a direct connection (i.e., touching) unless the context indicates otherwise.

The first power supply 512 may include a first sub power supply 512-1 configured to supply powers to the first subgroup of heating elements 412-1, a second sub power supply 512-2 configured to supply powers to the second subgroup of heating elements 412-2 and a third sub power supply 512-3 configured to supply powers to the third subgroup of heating elements 412-3.

The second power supply 522 may include a fourth sub power sup 522-1 configured to supply powers to the fourth subgroup of heating elements 422-1, a fifth sub power supply 522-2 configured to supply powers to the fifth subgroup of heating elements 422-2 and a sixth sub power supply 522-3 configured to supply powers to the sixth subgroup of heating elements 422-3.

In example embodiments, the LED element may generate light having a wavelength of about 1100 nm or less. As illustrated in FIG. 8, according to transmissivity of silicon wafer for each wavelength band, it may be seen that light having a wavelength of 1100 nm or more may penetrate through the wafer without being absorbed. In an exemplary embodiment, the LED light source generating light having a wavelength of 1100 nm or less is used. The light is absorbed by the wafer, thereby increasing the temperature of the wafer. The intensity of the LED light may be selected such that a process of bonding two wafers has a bonding error between several hundred mm and several nm.

In FIG. 8, testing of various wafers with different doping doses (doping amount, W1<W2<W3<W4) showed that, regardless of the doping amount, transmissivity of the wafers may have similar changes with respect to a wavelength of light illuminated on the wafers. For example, the transmissivity of the wafers may sharply increase from near zero to values at about 1100 nm. In an exemplary embodiment where the LED light source having a wavelength of 1100 nm or less is used, the temperature of a wafer may increase. For example, the temperature increase of the wafer may be about 0.03° C. over a time scale of tens/hundreds of milliseconds when the LED light source generates light with a wavelength of 1070 nm at power consumption of 57 milliwatts (mW). Absorption rate of the light in this embodiment may be, for example, 77%.

Referring to FIG. 3, in a wafer bonding step, the middle portion of the second wafer W2 may be deformed using the upper push rod 322 to stretch downward, and then, may be joined gradually to the first wafer W1 from the middle region to the peripheral region. As the bonding proceeds in the radial direction, when a deformation difference between the first wafer W1 and the second wafer W2 occurs, a position error between the junction points located on each wafers may be generated, which may be referred to as a bonding error (alignment error).

The bonding error may be caused by anisotropy of the wafer material. The wafer may be an anisotropic crystalline material whose physical properties are determined by the orientation of the crystal lattice. As illustrated in FIGS. 9A and 9B, since the wafer bonding process is a process of bonding two wafers, an alignment error map may vary according to the difference in the crystal orientations of the two wafers. The alignment error map of FIG. 9A shows bonding error information when the first and second wafers have the same crystal orientation (e.g., [100]) with respect to a notch on a perimeter of each of the first second wafers, and the alignment error map of FIG. 9B shows bonding error information when the first wafer has a first crystal orientation (e.g., [110]) with respect to a notch on a perimeter of the first wafer and the second wafer has a second crystal orientation (e.g., [100]) with respect to a notch on a perimeter of the second wafer. In an exemplary embodiment, each of the first and second wafers may have a wafer notch to convey a crystal orientation of a wafer. Especially, as in FIG. 9B, the alignment error may occur periodically due to the anisotropy of the silicon wafer material. For example, angular distance between two alignment errors may correspond to 45 degrees.

Additionally, the bonding error may be caused by an initial deformation of a wafer called warpage. The initial deformation of the wafer may be caused by residual stress inside the wafer caused by various processes performed prior to the wafer bonding process. This warpage may be defined as a height difference between the center and the edge. The warpage may have various forms such as concave, convex and saddle forms.

In example embodiments, in order to compensate the bonding error, heating values of the heating elements 400 may be controlled independently to perform local heat treatment. For the local heat treatment, heating values of the first subgroup of heating elements 412-1, the second subgroup of heating elements 412-2, the third subgroup of heating elements 412-3, the fourth subgroup of the heating elements 422-1, the fifth subgroup of the heating elements 422-2 and the sixth subgroup of the heating elements 422-3 may be determined using the bonding error information. For example, each of the first subgroup of heating elements 412-1, the second subgroup of heating elements 412-2, the third subgroup of heating elements 412-3, the fourth subgroup of the heating elements 422-1, the fifth subgroup of the heating elements 422-2 and the sixth subgroup of the heating elements 422-3 may be separately controlled in a wafer bonding process using the bonding error information.

The controller 600 may obtain the bonding error information of the first and second wafers before performing the wafer boding process, control independently the heating values of the heating elements 400 to perform the local heat treatment on the first wafer and/or the second wafer, and proceed with the wafer bonding process.

As illustrated in FIG. 10, it may be seen that bonding error between the first and second wafers bonded by the wafer bonding apparatus having the heating device according to an example embodiment may be reduced compared to a wafer bonding device, as a comparative embodiment without the heating device.

As described above, the wafer bonding apparatus 70 may include a plurality of the heating elements 400 provided in the upper stage 210 (and/or lower stage 110) to heat the second wafer W2 (and/or first wafer W1). The wafer bonding apparatus 70 may control independently the heating values of the heating elements 400 based on the bonding error information to perform the local heat treatment on the second wafer W2 (and/or first wafer W1), before bonding the first and second wafers W1 and W2. In an exemplary embodiment, the local heat treatment may be performed so that the first and second wafers have a temperature distribution corresponding to the bonding error information, and then, the bonding of the first and second wafers W1 and W2 starts.

Thus, heat from the heating elements 400 may be transferred to the wafer in contact or non-contact form to thereby minimize the bonding error between the first and second wafers.

Hereinafter, the wafer bonding apparatus in FIG. 1 will be explained with reference to FIG. 11.

FIG. 11 is a plan view illustrating an alignment apparatus in accordance with example embodiments.

Referring to FIG. 11, an alignment apparatus 60 may include an alignment stage 62 configured to support and align a wafer W. The alignment stage 62 may have a third surface 64 on which the wafer W is disposed.

Suction holes (not illustrated) may be provided in the third surface 64. The wafer may be vacuum suctioned by the suction holes of the alignment stage 62. Alternatively, the wafer may be held by an electrostatic chuck using an electrostatic force.

The alignment apparatus 60 may include an alignment stage driving portion (not illustrated) which moves the alignment stage 62. The alignment stage driving portion may include a horizontal driving portion to move linearly the alignment stage 62 in X, Y, Z directions and a rotational driving portion to rotate the alignment stage 62 about Z axis.

In example embodiments, the alignment apparatus 60 may include a heating device which includes a plurality of heating elements 700 provided in the third surface 64 of the alignment stage 62 to heat the wafer W. Powers of the heating elements 700 may be controlled independently to perform local heat treatment on the wafer. The powers of a plurality of the heating elements 700 may be controlled independently such that the wafer is heated to have different temperature distributions along a circumferential direction about a center of the wafer.

The plurality of the heating elements 700 may include a first group of heating elements 712 disposed in a first region and a second group of heating elements 722 disposed in the second region.

The first group of heating elements 712 may include a first subgroup of heating elements 712-1, a second subgroup of heating elements 712-2 and a third subgroup of heating elements 712-3 disposed in first, second and third sub-regions respectively. The second group of heating elements 722 may include a fourth subgroup of heating elements 722-1, a fifth subgroup of heating elements 722-2 and a sixth subgroup of heating elements 722-3 disposed in fourth, fifth and sixth sub-regions respectively.

The heating device may be substantially the same as or similar to the heating device described with reference to FIGS. 4 to 7. Thus, same reference numerals will be used to refer to the same or like elements and any further repetitive explanation concerning the above elements will be omitted.

As mentioned above, instead of providing the heating device to the upper chuck of the wafer bonding apparatus, the heating device may be provided to the alignment apparatus 60 that loads the wafer into the wafer bonding apparatus.

Thus, before loading the wafer into the wafer bonding apparatus, local heat treatment may be performed on the wafer based on bonding error information such that the wafer have a desired temperature distribution. The transfer robot 22 may hold and transfer the wafer W to the wafer bonding apparatus while maintaining the shape deformed by the local heat treatment. In this case, since the wafer can be heated to have a desired temperature distribution in the state where the wafer is held on the alignment apparatus 60, the heating element may be implemented using various heaters, other than an LED element as described above, utilizing conductive heat transfer.

Hereinafter, a wafer to wafer bonding method using the wafer to wafer bonding system in FIG. 1 will be described with reference to FIGS. 12 to 14.

FIG. 12 is a flowchart illustrating a wafer to wafer bonding method in accordance with example embodiments. FIG. 13 is a view illustrating the wafer to wafer bonding method in FIG. 12. FIG. 14 is a flowchart illustrating a bonding stage of the wafer to wafer bonding method in FIG. 12.

Referring to FIGS. 1 to 7, 11, and 12 to 13, a pre-treatment may be performed on at least one of bonding surfaces of wafers to be bonded to each other (S100).

In example embodiments, the wafers W1 and W2 may be loaded into a chamber of the plasma processing apparatus 40, a plasma gas may be supplied on the wafers W1 and W2 through a shower head, and a plasma process may then be performed within the chamber.

Then, the surface of the wafer that has been plasma-processed may be cleaned. DI water may be coated on the wafer surface using a spin coater of the cleaning apparatus 50. The DI water may clean the wafer surface and allow —OH radical to be bonded easily on the wafer surface, such that dangling bonds are easily created on the wafer surface.

Then, the pre-treatment processed wafers W1 and W2 may be aligned (S110), the middle portion of the wafer W1 may be pressed such that the middle portion of the wafer W1 stretches (S120), and then, the wafers W1 and W2 may be gradually joined from the middle portion to a peripheral region such that the wafers W1 and W2 are joined (S130).

In example embodiments, the pre-treatment processed first and second wafers W1 and W2 may be suctioned to be held on the lower stage 110 and the upper stage 210 respectively. The first wafer W1 may be vacuum suctioned by the first suction holes 130 formed in the lower stage 110. The second wafer W2 may be vacuum suctioned by the second suction holes 230 formed in the upper stage 210.

Then, the upper push rod 322 may move toward the lower stage 110 to press the middle portion of the second wafer W2. Thus, the middle portion of the second wafer W2 may be detached from the second surface 212 of the upper stage 210 to stretch downward while the peripheral region is held.

When the second wafer W2 bends downward such that it is downwardly concave, the lower stage 110 may travel upward such that the first wafer W1 contacts the second wafer W2. The bonding starts when the middle portion of the first wafer W1 initially contacts the middle portion of the second wafer W2. In here, a distance between the lower stage 110 and the upper stage 210 may be maintained between about 50 mm and about 150 mm.

At the bonding initial time, vacuum pressure may be applied to the first to third suction portions Z1, Z2, Z3 of the upper stage 210 and vacuum pressure may be applied to the third suction portion Z3 of the lower stage 110. Thus, a suction region of a first suction area may be formed in the peripheral region of the upper stage 210, and a suction region of a third suction area less than the first suction area may be formed in the peripheral region of the lower stage 110.

In this case, as illustrated in FIG. 14, alignment error information between the first and second wafers W1 and W2 may be obtained (S1302), local heat treatment may be performed on the second wafer W2 (and/or first wafer W1) based on the information (S1304), and then, the bonding process of the first and second wafers W1, W2 may be performed (S1306).

For example, the alignment error information may be obtained from the aligned wafers W1 and W2 using a detection sensor such as a vision camera after the alignment (S110) is performed. The bonding error information of the bonded first and second wafers W1, W2 may be obtained.

In order to compensate the alignment error, heating values of the heating elements 400 may be controlled independently to perform local heat treatment. For the local heat treatment, heating values of the first subgroup of heating elements 412-1, the second subgroup of heating elements 412-2, the third subgroup of heating elements 412-3, the fourth subgroup of the heating elements 422-1, the fifth subgroup of the heating elements 422-2 and the sixth subgroup of the heating elements 422-3 may be determined using the bonding error information.

The powers of a plurality of the heating elements 400 may be controlled independently such that the second wafer W2 is heated to have different temperature distributions along a circumferential direction about a center of the second wafer. For example, the second wafer W2 may be heated to have a first temperature in a first crystal orientation of the second wafer W2 and a second temperature different from the first temperature in a second crystal orientation of the second wafer W2 different from the first orientation. The first crystal orientation and the second crystal orientation may have an angle of 45° in the circumferential direction about the center.

The local heat treatment may be performed on the second wafer W2 based on the alignment error information, to thereby minimize the bonding error between the adhesion points of the first and second wafers W1, W2.

The above-described wafer to wafer bonding system and wafer to wafer bonding method may be used to manufacture, for example, semiconductor packages or image sensors including logic devices and memory devices. For example, the semiconductor packages may include volatile memory devices such as DRAM devices and SRAM devices, or non-volatile memory devices such as flash memory devices, PRAM devices, MRAM devices, ReRAM devices, etc. The image sensor may include a CMOS image sensor.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A wafer bonding apparatus, comprising:
a lower stage having a first surface and configured to hold a first wafer on the first surface;
an upper stage having a second surface and configured to hold a second wafer on the second surface;
an upper push rod configured to pass through a center hole of the upper stage to press a middle region of the second wafer; and
a plurality of first heating circuits provided at the second surface of the upper stage to heat the second wafer held by the upper stage,
wherein each of the plurality of first heating circuits is configured to be independently controlled such that the second wafer is heated to have different temperature distributions along a circumferential direction about a center of the second wafer.

2. The wafer bonding apparatus of claim 1,
wherein the plurality of first heating circuits comprise a plurality of first groups of first heating circuits and a plurality of second groups of first heating circuits, and
wherein the plurality of first groups of first heating circuits are alternately arranged with the plurality of second groups of first heating circuits in the circumferential direction.

3. The wafer bonding apparatus of claim 2,
wherein each of the plurality of first groups of first heating circuits is adjacent to a respective region of a plurality of first regions of the second wafer held by the upper stage,
wherein each of the plurality of second groups of first heating circuits is adjacent to a respective region of a plurality of second regions of the second wafer held by the upper stage,
wherein the plurality of first regions are alternately arranged with the plurality of second regions along the circumferential direction, and
wherein each of the plurality of first regions and each of the plurality of second regions are a pie-shaped region with a central angle of 45°.

4. The wafer bonding apparatus of claim 2,
wherein each of the plurality of first groups of first heating circuits comprises a first subgroup of heating circuits, a second subgroup of heating circuits and a third subgroup of heating circuits disposed in first, second and third sub-regions arranged sequentially in a radial direction from the center, respectively.

5. The wafer bonding apparatus of claim 4,
wherein the first sub-region is pie-shaped,
wherein a first arc is located at a boundary between the first sub-region and the second sub-region,
wherein a second arc is located at a boundary between the second sub-region and the third sub-region, and
wherein the first arc is closer to the center than the second arc.

6. The wafer bonding apparatus of claim 1,
wherein each of the plurality of first heating circuits comprises a light-emitting-diode (LED).

7. The wafer bonding apparatus of claim 6,
wherein the LED is configured to generate light having a wavelength up to 1100 nm.

8. The wafer bonding apparatus of claim 1, further comprising:
a power controller configured to independently control a heating value of each of the plurality of first heating circuits on a respective region of the second wafer held by the upper stage.

9. The wafer bonding apparatus of claim 8, further comprising:
a plurality of second heating circuits provided at the first surface of the lower stage to heat the first wafer,
wherein the power controller is configured to control the plurality of the first heating circuits so that the second wafer is heated to have a first temperature in a first crystal orientation of the second wafer and to control the plurality of second heating circuits so that the first wafer is heated to have a second temperature, different from the first temperature, in a second crystal orientation of the first wafer different from the first crystal orientation.

10. The wafer bonding apparatus of claim 1, further comprising:
a plurality of second heating circuits provided at the first surface of the lower stage,
wherein a heating value of each of the plurality of second heating circuits is independently controlled such that the first wafer is heated to have different temperature distributions along a circumferential direction about a center of the first wafer.

11. A wafer bonding apparatus, comprising:
a lower stage having a first surface and configured to hold a first wafer on the first surface;
an upper stage having a second lower surface and a second upper surface opposite thereto,
wherein the second lower surface is configured to hold a second wafer, and
wherein the upper stage includes a center hole extending from the second upper surface to the second lower surface;
an upper push rod configured to pass through the center hole of the upper stage to press a middle region of the second wafer;
a plurality of first heating circuits provided at the second lower surface of the upper stage to heat the second wafer; and
a power controller configured to independently control the plurality of first heating circuits to perform a first local heat treatment on a first region of the second wafer and a second local heat treatment on a second region of the second wafer.

12. The wafer bonding apparatus of claim 11,
wherein the power controller includes a first power supply and a second power supply,
wherein the first power supply is electrically connected to a first set of first heating circuits among the plurality of first heating circuits and is configured to control the first set of first heating circuits for the first local heat treatment,
wherein the second power supply is electrically connected to a second set of first heating circuits among the plurality of first heating circuits and is configured to control the second set of first heating circuits for the second local heat treatment, and
wherein the first power supply and the second power supply are configured to independently control the plurality of first heating circuits such that the second wafer has temperature distributions along a circumferential direction about a center of the second wafer.

13. The wafer bonding apparatus of claim 11, further comprising:
a plurality of second heating circuits provided at the first surface of the lower stage to heat the first wafer,
wherein the power controller is configured to control the plurality of the first heating circuits so that the second wafer is heated to have a first temperature in a first crystal orientation of the second wafer and to control the plurality of second heating circuits so that the first wafer is heated to have a second temperature, different from the first temperature, in a second crystal orientation of the first wafer different from the first crystal orientation.

14. The wafer bonding apparatus of claim 13,
wherein the first crystal orientation is different from the second crystal orientation by an angle of 45°.

15. The wafer bonding apparatus of claim 11,
wherein a plurality of the first heating circuits comprise a plurality of first groups of first heating circuits and a plurality of second groups of first heating circuits, and
wherein the plurality of first groups are alternately arranged with the plurality of second groups in a circumferential direction about a center of the second wafer held by the upper stage.

16. The wafer bonding apparatus of claim 15,
wherein each of the plurality of first groups is disposed on a respective region of a plurality of first regions of the second wafer,
wherein each of the plurality of second groups is disposed on a respective region of a plurality of second regions of the second wafer,
wherein the plurality of first regions are alternately arranged with the plurality of second regions along the circumferential direction, and
wherein each of the plurality of first regions and each of the plurality of second regions are a pie-shaped region with a central angle of 45°.

17. The wafer bonding apparatus of claim 15,
wherein each of the plurality of first groups of first heating circuits comprises at least two subgroups of first heating circuits arranged sequentially in a radial direction from the center.

18. The wafer bonding apparatus of claim 11,
wherein each of the plurality of first heating circuits comprises a light-emitting diode (LED).

19. (canceled)

20. The wafer bonding apparatus of claim 11, further comprising:
a plurality of second heating circuits provided in the first surface of the lower stage to heat the first wafer,
wherein the power controller is further configured to independently control the plurality of second heating circuits to perform a third local heat treatment on a first region of the first wafer and a third local heat treatment on a second region of the first wafer.

21. A wafer to wafer bonding system, comprising:
an alignment apparatus including an alignment stage and configured to load a first wafer and a second wafer on the alignment stage, wherein the alignment stage is configured to support and align the first wafer and the second wafer;
a wafer bonding apparatus configured to receive the aligned first wafer and the aligned second wafer and to bond the aligned first wafer and the aligned second wafer to each other,
wherein the wafer bonding apparatus includes an upper stage and a lower stage which are configured to hold the aligned first wafer and the aligned second wafer, respectively;
a plurality of first heating circuits provided in the upper stage to heat the aligned first wafer; and
a power controller configured to independently control a heating value of each of the plurality of first heating circuits on a respective region of the aligned first wafer.

22-28. (canceled)
